(19) United States
(12) Patent Application Publication
(10) Pub. No.: US 2015/0072561 A1
(43) Pub. Date: Mar. 12, 2015

(54) CAGE WITH EMI ABSORBER

(71) Applicant: Tyco Electronics Corporation

(72) Inventors: Matthew R. Schmitt, Middletown, PA (US); Richard James Long, Columbia, PA (US); Steven David Dunwoody, Middletown, PA (US)

(73) Assignee: Tyco Electronics Corporation

(21) Appl. No.: 14/020,172

(22) Filed: Sep. 6, 2013

(51) Int. Cl. H05K 9/00; H01R 13/6581

(52) U.S. Cl. CPC H05K 9/002; H01R 13/6581
USPC 439/607.55; 174/359

(57) ABSTRACT

A cage is provided for a receptacle assembly that includes a receptacle connector. The cage includes a body having an upper wall, a lower wall, and side walls that extend from the upper wall to the lower wall. The body has a lower side along which the lower wall extends, a front end, and an internal compartment. The internal compartment is configured to hold the receptacle connector therein. The internal compartment is configured to receive a pluggable module therein through the front end. The cage is configured to be mounted to a printed circuit along the lower side. The lower side includes a connector opening. An electromagnetic interference (EMI) absorber extends over at least a portion of the lower wall. The EMI absorber is configured to absorb EMI.

### BACKGROUND OF THE INVENTION

The subject matter described and/or illustrated herein relates generally to receptacle assemblies, and more particularly to the metal cages of receptacle assemblies.

Various types of fiber optic and copper based electrical connector assemblies that permit communication between host equipment and external devices are known. These electrical connector assemblies typically include a pluggable module that is received within a receptacle assembly, which includes a receptacle connector that pluggably connects to the pluggable module. Receptacle assemblies typically include a metal cage having an internal compartment that receives the pluggable module therein. The receptacle connector is held in the cage for connection with the pluggable module as the module is inserted into the cage. The pluggable modules are constructed according to various standards for size and compatibility, for example the Quad Small Form-factor Pluggable (QSFP) module standard and the XFP standard.

One particular concern regarding receptacle assemblies is reducing electromagnetic interference (EMI) emissions. Due to government regulations, there is a need not only to minimize the EMI emissions of the electrical connector assembly, but also to contain the EMI emissions of the host system in which the electrical connector assembly is mounted, regardless of whether a pluggable module is plugged in to the receptacle. In at least some known receptacle assemblies, EMI shielding is achieved using the metal cage. However, due to increasing signal speeds being transmitted through the electrical connector assemblies, the EMI shielding provided by conventional cages is proving to be inadequate.

Accordingly, there is a need for an electrical connector assembly that reduces EMI emissions.

### BRIEF DESCRIPTION OF THE INVENTION

In an embodiment, a cage is provided for a receptacle assembly that includes a receptacle connector. The cage includes a body having an upper wall, a lower wall, and side walls that extend from the upper wall to the lower wall. The body has a lower side along which the lower wall extends, a front end, and an internal compartment. The internal compartment is configured to hold the receptacle connector therein. The internal compartment is configured to receive a pluggable module therein through the front end. The cage is configured to be mounted to a printed circuit along the lower side. The lower side includes a connector opening. An electromagnetic interference (EMI) absorber extends over at least a portion of the lower wall. The EMI absorber is configured to absorb EMI.

In an embodiment, a receptacle assembly is provided for mating with a pluggable module. The receptacle assembly includes a receptacle connector, and a cage that includes a body having an upper wall, a lower wall, and side walls that extend from the upper wall to the lower wall. The body has a lower side along which the lower wall extends, a front end, and an internal compartment. The receptacle connector is held within the internal compartment. The internal compartment is configured to receive the pluggable module therein through the front end. The cage is configured to be mounted to a printed circuit along the lower side. The lower side includes a connector opening. The cage includes an electromagnetic interference (EMI) absorber that extends over at least a portion of the lower wall. The EMI absorber is configured to absorb EMI.

In an embodiment, a cage is provided for a receptacle assembly that includes a receptacle connector. The cage includes a body having an upper wall, a lower wall, and side walls that extend from the upper wall to the lower wall. The body has a lower side along which the lower wall extends, a front end, and an internal compartment. The internal compartment is configured to hold the receptacle connector therein. The internal compartment is configured to receive a pluggable module therein through the front end. The cage is configured to be mounted to a printed circuit along the lower side. The lower side includes a connector opening. The cage includes an electromagnetic interference (EMI) absorber that is configured to absorb EMI. The EMI absorber extends along a perimeter of the lower wall.

### BRIEF DESCRIPTION OF THE DRAWINGS

FIG. 1 is an exploded perspective view of an embodiment of an electrical connector assembly.

FIG. 2 is a cross-sectional view of the electrical connector assembly shown in FIG. 1 illustrating an embodiment of a pluggable module mated with an embodiment of a receptacle assembly.

FIG. 3 is a perspective view of an embodiment of a cage of the electrical connector assembly shown in FIGS. 1 and 2.

FIG. 4 is another perspective view of the cage illustrating an embodiment of an electromagnetic interference (EMI) absorber of the cage.

### DETAILED DESCRIPTION OF THE INVENTION

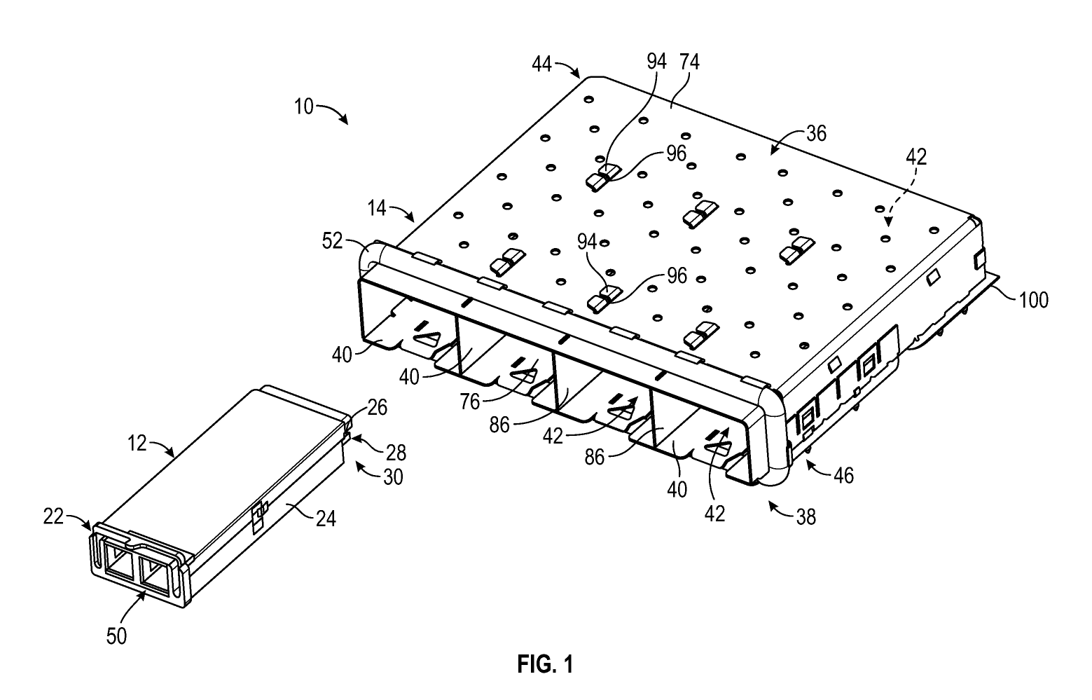

FIG. 1 is a perspective view of a portion of an embodiment of an electrical connector assembly 10. The electrical connector assembly 10 may be commonly referred to as a “transceiver assembly”. In an embodiment, the electrical connector assembly 10 is adapted to address, among other things, conveying data signals at high rates, such as, but not limited to, data transmission rates of at least 10 gigabits per second (Gbps), which is required by the SFP+ standard. For example, in some embodiments the electrical connector assembly 10 is adapted to convey data signals at a data transmission rate of at least 28 Gbps. Moreover, and for example, in some embodiments the electrical connector assembly 10 is adapted to convey data signals at a data transmission rate of between approximately 20 Gbps and approximately 30 Gbps. It is appreciated, however, that the benefits and advantages of the subject matter described and/or illustrated herein may accrue equally to other data transmission rates and across a variety of systems and standards. In other words, the subject matter described and/or illustrated herein is not limited to data transmission rates of 10 Gbps or greater, any standard, or the exemplary type of electrical connector and/or transceiver assembly shown and described herein.

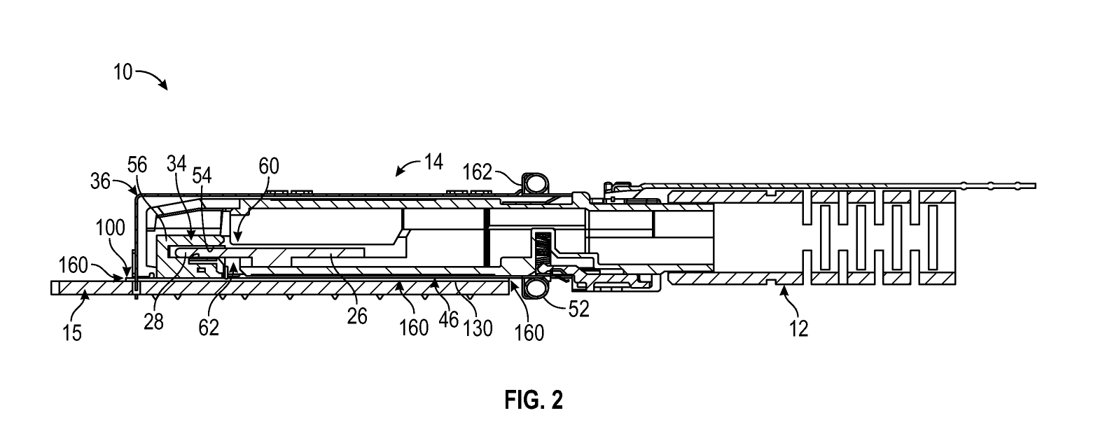

The electrical connector assembly 10 includes one or more pluggable modules 12 configured for pluggable insertion into a receptacle assembly 14 that is mounted on a host circuit board 15 (FIG. 2). The host circuit board 15 may be mounted in a host system (not shown) such as, but not limited to, a router, a server, a computer, and/or the like. The host system typically includes a conductive chassis (not shown) having a panel (not shown) including one or more openings (not shown) extending therethrough in substantial alignment with the receptacle assembly 14. The receptacle assembly 14 is optionally electrically connected to the panel. Only one pluggable module 12 is shown in FIG. 1 for clarity. The host circuit board 15 may be referred to herein as a “printed circuit”.

The pluggable module 12 is configured to be inserted into the receptacle assembly 14. Specifically, the pluggable module 12 is inserted into the receptacle assembly 14 through the panel opening such that a front end 22 of the pluggable module 12 extends outwardly from the receptacle assembly 14. The pluggable module 12 includes a housing 24 that forms a protective shell for a circuit board 26 that is disposed within the housing 24. The circuit board 26 will be referred to herein as a “module circuit board” and carries circuitry, traces, paths, devices, and/or the like that perform transceiver functions in a known manner. An edge 28 of the module circuit board 26 is exposed at a rear end 30 of the housing 24. In the illustrated embodiment, the module circuit board 26 of the pluggable module 12 directly mates with a receptacle connector 34 (FIG. 2) of the receptacle assembly 14. In other words, the edge 28 of the module circuit board 26 of the pluggable module 12 is received within a receptacle 54 (FIG. 2) of the receptacle connector 34 to electrically connect the pluggable module 12 to the receptacle connector 34. Alternatively, a straddle mount connector (not shown) is mounted to the module circuit board 26 and exposed at the rear end 30 of the housing 24 for plugging into the receptacle 54 of the receptacle connector 34.

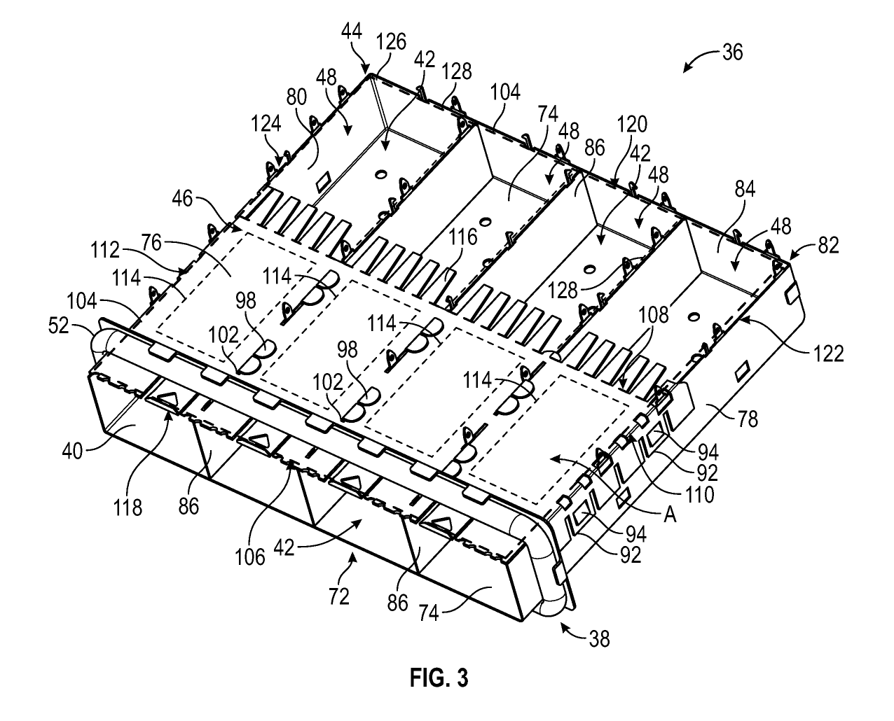

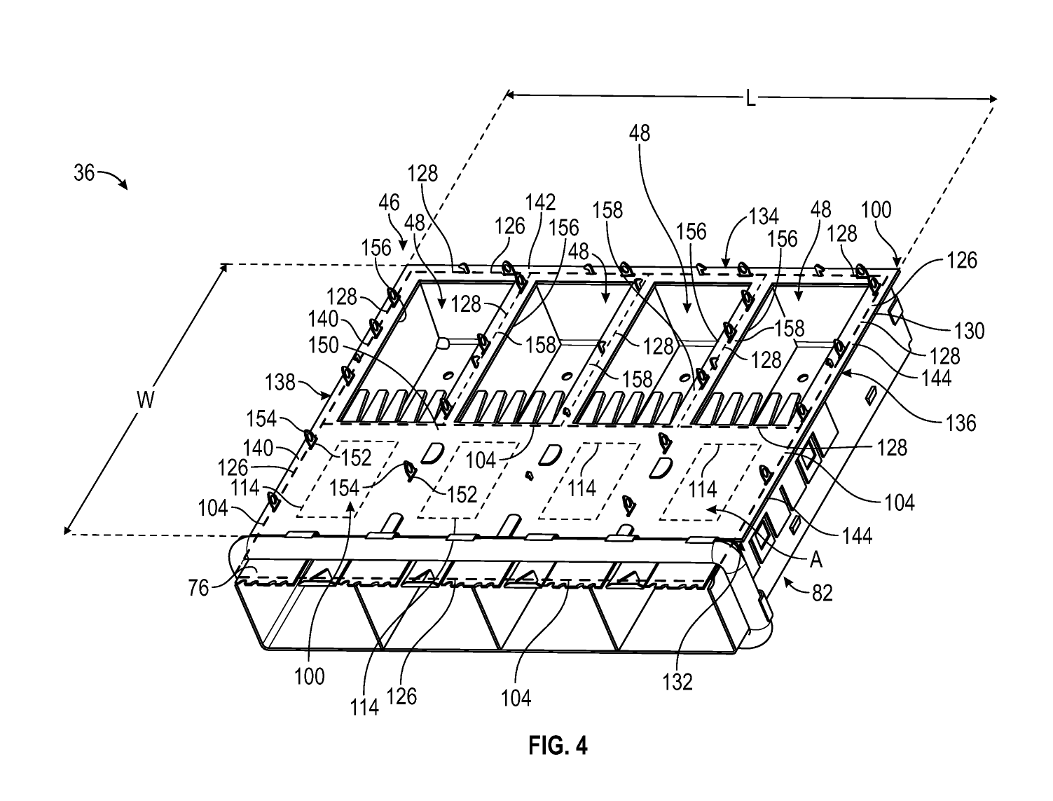

In general, the pluggable module 12 and the receptacle assembly 14 may be used in any application requiring an interface between a host system and electrical and/or optical signals. Each pluggable module 12 interfaces to the host system through the receptacle assembly 14 via the corresponding receptacle connector 34 of the receptacle assembly 14, which is located within an electrically conductive cage 36 (which is sometimes referred to as a “receptacle guide frame” or a “guide frame”) of the receptacle assembly 14. As illustrated in FIG. 1, the cage 36 includes a front end 38 having one or more front openings, or ports, 40 that are open to corresponding internal compartments 42 of the cage 36. The front end 38 of the cage 36 is configured to be mounted, or received, within the opening in the panel. A receptacle connector 34 (FIG. 2) is positioned within each internal compartment 42 at a rear end 44 of the cage 36. The cage 36 is configured to be mounted to the host circuit board 15 along a lower side 46 of the cage 36. The lower side 46 of the cage 36 includes one or more openings 48 (FIGS. 3 and 4) for enabling each receptacle connector 34 to electrically connect to the host circuit board 15 from within the corresponding internal compartment 42. Each internal compartment 42 of the cage 36 is configured to receive the corresponding pluggable module 12 therein in electrical connection with the corresponding receptacle connector 34. Each of the openings 48 may be referred to herein as a “connector opening”.

Each pluggable module 12 interfaces to one or more optical cables (not shown) and/or one or more electrical cables (not shown) through a connector interface 50 at the front end 22 of the module 12. Optionally, the connector interface 50 comprises a mechanism that cooperates with a fiber or cable assembly (not shown) to secure the fiber or cable assembly to the pluggable module 12. Suitable connector interfaces 50 are known and include adapters for the LC style fiber connectors and the MTP/MPO style fiber connectors offered by TE Connectivity (Harrisburg, Pa.).

Although the cage 36 is shown as including a plurality of internal compartments 42 and a plurality of ports 40 for electrically connecting a plurality of pluggable modules 12 to the host circuit board 15, the cage 36 may include any number of internal compartments 42 and ports 40, arranged in any pattern, configuration, arrangement, and/or the like (such as, but not limited to, any number of rows and/or columns), for electrically connecting any number of pluggable modules 12 to the host circuit board 15. Optionally, an electromagnetic interference (EMI) gasket 52 extends circumferentially about one or more of the ports 40. The EMI gasket 52 is configured to block EMI from leaking through an interface between the front end 38 of the cage 36 and the panel (not shown) to which the cage 36 is mounted.

As will be described in more detail below, the cage 36 includes an electromagnetic interference (EMI) absorber 100 that extends along the lower side 46 of the cage 36 and over at least a portion of a lower wall 76 of the cage 36. The EMI absorber 100 is configured to absorb EMI.

FIG. 2 is a cross-sectional view of the electrical connector assembly 10 illustrating a pluggable module 12 received within the receptacle assembly 14 and mated with the corresponding receptacle connector 34. The receptacle connector 34 is mounted on the host circuit board 15. The receptacle connector 34 includes a dielectric connector body 56 having the receptacle 54.

The receptacle 54 of the receptacle connector 34 receives the edge 28 of the module circuit board 26 of the pluggable module 12 therein. The receptacle connector 34 includes electrical contacts (not shown) that extend within the receptacle 54 and engage corresponding electrical contacts (not shown) on opposite sides 60 and 62 of the module circuit board 26 to establish an electrical connection between the module circuit board 26 of the pluggable module 12 and the host circuit board 15 through the receptacle connector 34.

FIG. 3 is a perspective view of the cage 36. The cage 36 includes an electrically conductive body 82. The body 82 of the cage 36 extends a length from the front end 38 to the rear end 44, and includes the lower side 46 and an upper side 72 that is opposite the lower side 46. The cage body 82 includes an upper wall 74 (also labeled in FIG. 1), the lower wall 76, and side walls 78 and 80 that extend from the upper wall 74 to the lower wall 76. The body 82 of the cage 36 also includes a rear wall 84 that extends from the upper wall 74 at the rear end 44. Optionally, the cage body 82 includes one or more divider walls 86 that divide the body 82 into the plurality of internal compartments 42. The cage body 82 may include any number of the divider walls 86 for dividing the body 82 into any number of internal compartments 42. In some alternative embodiments, the body 82 of the cage 36 does not include any divider walls 86 such that the body 82 includes only a single internal compartment 42.

The upper wall 74 extends along, and defines at least a portion of, the upper side 72 of the body 82. The lower wall 76 extends along, and defines at least a portion of, the lower side 46 of the body 82. In the illustrated embodiment, the cage 36 includes a generally rectangular cross-sectional shape, defined by the walls 74, 76, 78, and 80, such that the cage 36 generally has the shape of a parallelepiped. But, the cage 36 may include any other shape.

In the illustrated embodiment, the side walls 78 and 80 and the rear wall 84 of the cage body 82 are each integrally formed as a single, unitary piece with the upper wall 74, while the lower wall 76 is a discrete component (of the cage body 82) relative to the upper wall 74, the rear wall 84, and the side walls 78 and 80. The lower wall 76 is mechanically connected to each of the side walls 78 and 80 using any suitable connection structure, means, type, and/or the like that enables a mechanical connection between the lower wall 76 and the side walls 78 and 80. In the illustrated embodiment, the lower wall 76 includes one or more mounting clips 92 that engage one or more corresponding mounting tabs 94 on the side walls 78 and 80 with a snap-fit connection to mechanically connect the lower wall 76 to the side walls 78 and 80. In addition or alternatively to being integrally formed with the upper wall 74 and/or the rear wall 84, the side walls 78 and/or 80 may be integrally formed with the lower wall 76. Moreover, the rear wall 84 may be a discrete component of the cage body 82 relative to the upper wall 74 and/or the side walls 78 and/or 80, and each of the side walls 78 and/or 80 may be a discrete component of the cage body 82 relative to the upper wall 74, the rear wall 84, and/or the lower wall 76.

The divider walls 86 of the cage body 82 are discrete components of the cage body 82 relative to the upper wall 74 and the lower wall 76 in the illustrated embodiment. Each divider wall 86 is mechanically connected to the upper wall 74 and the lower wall 76 using any suitable connection structure, means, type, and/or the like that enables a mechanical connection therebetween. In the illustrated embodiment, the divider walls 86 are mechanically connected to the upper wall 74 via one or more mounting tabs 94 that are received within one or more corresponding slots 96 that extend within the upper wall 74, as can be seen in FIG. 1. Referring again to FIG. 3, the divider walls 86 are mechanically connected to the lower wall 76 through one or more mounting tabs 98 that extend through one or more corresponding slots 102 within the lower wall 76. In some alternative embodiments, one or more of the divider walls 86 is integrally formed with the upper wall 74 and/or the lower wall 76.

The lower wall 76 includes a perimeter 104, which is defined by a front edge 106, a rear edge 108, and opposite side edges 110 and 112 of the lower wall 76. A surface area A of the lower wall 76 is defined between the edges 106, 108, 110, and 112. The lower wall 76 includes a plurality of interior segments 114 that are spaced apart from the edges 106, 108, 110, and 112. Optionally, a plurality of spring fingers 116 extend outward from the rear edge 108 to facilitate grounding the lower side 46 of the cage body 82 to the host circuit board 15 (FIG. 2). The front edge 106 of the lower wall 76 optionally includes latch elements 118 for latching the pluggable modules 12 (FIGS. 1 and 2) within the corresponding internal compartments 42.

The rear wall 84 includes an edge 120. The side walls 78 and 80 include respective edges 122 and 124. The edges 106, 110, 112, 120, 122, and 124 define a portion of the lower side 46 of the cage body 82. Specifically, the edges 106, 110, 112, 120, 122, and 124 define a perimeter 126 of the lower side 46 of the cage body 82. As can be seen in FIG. 3, the openings 48 include perimeters 128 that are defined by the edges 108, 120, 122, and 124.

FIG. 4 is another perspective view of the cage 36 illustrating an embodiment of the EMI absorber 100. As can be seen in FIG. 4, the EMI absorber 100 extends along the lower side 46 of the cage 36 and over the lower wall 76 of the cage 36. In the illustrated embodiment, the EMI absorber 100 is an approximately planar sheet of material 130 that extends a width W from front edge 132 to a rear edge 134. The sheet of material 130 extends a length L from a side edge 136 to an opposite side edge 138. Although shown as having a generally rectangular shape, the sheet of material 130 of the EMI absorber 100 may include any other shape.

The sheet of material 130 of the EMI absorber 100 may extend over any amount of, and location(s) along, the lower side 46 of the cage 36. In the illustrated embodiment, the sheet of material 130 extends along the perimeter 126 of the lower side 46, over the lower wall 76, and between adjacent connector openings 48 for absorbing EMI along the perimeter 126, along the lower wall 76, and between adjacent connector openings 48. For example, segments 140, 142, and 144 of the sheet of material 130 extend along the perimeter 126. In some embodiments, the sheet of material 130 may extend along an approximate entirety of the perimeter 126. For example, the sheet of material 130 may include a segment (not shown) that extends along the front edge 106 of the perimeter 126.

The sheet of material 130 of the EMI absorber 100 extends over the lower wall 76. Specifically, in the illustrated embodiment, the sheet of material 130 extends over the interior segments 114 of the lower wall 76 and along the perimeter 104 of the lower wall 76. The segments 140 and 144 and a segment 150 of the sheet of material 130 extend along the perimeter 104 for absorbing EMI along the perimeter 104. The sheet of material 130 extends over a majority of the surface area A of the lower wall 76 in the illustrated embodiment. But, the sheet of material 130 of the EMI absorber 100 may extend over any amount of, and location(s) along, the lower wall 76 of the cage 36. For example, the sheet of material 130 may extend over less than a majority of the surface area A of the lower wall 76. Moreover, and for example, the sheet of material 130 may extend along an approximate entirety of the perimeter 104. For example, the sheet of material 130 may include a segment (not shown) that extends along the front edge 106 of the perimeter 104. As shown in FIG. 4, the sheet of material 130 of the EMI absorber 100 includes openings 152 for tines 154 of the cage 36 that engage the host circuit board 15 (FIG. 2).

The sheet of material 130 includes one or more openings 156. Each opening 156 is at least partially aligned with a corresponding opening 48 of the lower side 46 of the cage 36. The at least partial alignment between the corresponding openings 156 and 48 enables the corresponding receptacle connector 34 (FIG. 2) to communicate with the host circuit board 15 through the corresponding openings 156 and 48. Although shown as having the same approximate size as the openings 48, each opening 156 may have any size relative to the corresponding opening 48. Each of the openings 156 may be referred to herein as a “cage opening”.

In the illustrated embodiment, the sheet of material 130 of the EMI absorber 100 extends along the perimeter 128 of each of the openings 48 of the lower side 46 for absorbing EMI along the perimeters 128. Although shown as extending along an approximate entirety of the perimeters 128, the sheet of material 130 may extend along only a portion of one or more of the perimeters 128. The sheet of material 130 may not extend along any of the perimeters 128 or may extend along only one or some of the perimeters 128 in other embodiments. Optionally, the sheet of material 130 includes segments 158 that extend between adjacent openings 48.

The EMI absorber 100 is optionally secured to the lower side 46 of the cage 36. The EMI absorber 100 may be secured to the lower side 46 of the cage 36 using any suitable method, structure, means, and/or the like, such as, but not limited to, using an interference fit (e.g., between the openings 152 and the tines 154), using an adhesive, using a tab, using a clip, and/or the like.

As briefly described above, the EMI absorber 100 is configured to absorb EMI. Specifically, the EMI absorber 100 has a relatively high permeability to absorb EMI. The EMI absorber 100 may be fabricated from any materials that provide the EMI absorber 100 with the relatively high permeability to absorb EMI, such as, but not limited to, a magnetic elastomer, rubber, nitrile, silicone, carbonal iron, a ferrite-based material, a ferrite material in a binder (e.g., a polymer binder), Viton® fluoroelastomer, neoprene, Hypolan® elastomer, urethane, an elastomeric material, and/or the like. The EMI absorber 100 may have magnetic fillers included within an elastomeric material, such as, but not limited to, a carbonyl iron powder, an iron silicide, other magnetic fillers, and/or the like. The type of material(s) within the EMI absorber 100 may be selected to target EMI at different frequencies. In some embodiments, the EMI absorber 100 includes a Q-Zorb™ material, commercially available from Laird Technologies.

Referring again to FIG. 2, when the receptacle assembly 14 is mounted on the host circuit board 15, the EMI absorber 100 is sandwiched between the lower side 46 of the cage 36 and the host circuit board 15. Specifically, the EMI absorber 100 is engaged in physical contact with both the lower side 46 of the cage 36 and the host circuit board 15 such that the EMI absorber 100 is engaged between the lower side 46 of the cage 36 and the host circuit board 15. Optionally, the EMI absorber 100 is compressed between the host circuit board 15 and the lower side 46 of the cage 36.

As described above, the EMI absorber 100 has a relatively high permeability to absorb EMI. The EMI absorber 100 is thus configured to absorb EMI emitted along the lower side 46 of the cage 36. By absorbing EMI emitted along the lower side 46 of the cage 36, the EMI absorber 100 may reduce or eliminate EMI leakage from an interface 160 between the lower side 46 of the cage 36 and the host circuit board 15. For example, the EMI absorber 100 may reduce or eliminate EMI leakage from the interface 160 along the perimeter 126 (FIG. 3) of the lower side 46 of the cage 36. Moreover, and for example, the EMI absorber 100 may reduce or eliminate EMI leakage from the interface 160 through the openings 48 (FIGS. 2 and 3). In some embodiments, the EMI absorber 100 eliminates substantially all EMI leakage from the interface 160. Optionally, the EMI absorber 100 abuts an optional bracket 162 of the cage 36 that may hold the optional EMI gasket 52 (FIG. 3). The efficiency of the EMI absorber 100 may depend on the formulation and application (e.g., thickness of the sheet of material 130, relative permeability, size, location, and/or the like) of the EMI absorber 100.

The embodiments described and/or illustrated herein may provide an electrical connector assembly that reduces EMI emissions.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

What is claimed is:

1. A cage for a receptacle assembly that includes a receptacle connector, the cage comprising:
a body comprising an upper wall, a lower wall, and side walls that extend from the upper wall to the lower wall, the body having a lower side along which the lower wall extends, a front end, and an internal compartment, the internal compartment being configured to hold the receptacle connector therein, the internal compartment being configured to receive a pluggable module therein through the front end, the cage being configured to be mounted to a printed circuit along the lower side, the lower side comprising a connector opening; and
an electromagnetic interference (EMI) absorber extending over at least a portion of the lower wall, the EMI absorber being configured to absorb EMI.

2. The cage of claim 1, wherein the EMI absorber comprises a sheet of material that extends over a majority of a surface area of the lower wall.

3. The cage of claim 1, wherein the EMI absorber comprises a cage opening that is at least partially aligned with the connector opening of the lower side such that the receptacle connector can communicate with the printed circuit through the cage and connector openings.

4. The cage of claim 1, wherein the lower wall comprises a perimeter, the EMI absorber extending along the perimeter of the lower wall.

5. The cage of claim 1, wherein the connector opening of the lower side comprises a perimeter, the EMI absorber extending along the perimeter of the connector opening.

6. The cage of claim 1, wherein the body of the cage comprises a rear wall that extends from the upper wall, the lower side of the body of the cage comprising edges of the rear wall and the side walls, the EMI absorber extending over the edge of at least one of the rear wall or at least one of the side walls.

7. The cage of claim 1, wherein the EMI absorber comprises an approximately planar sheet of material.

8. The cage of claim 1, wherein the internal compartment of the cage comprises two internal compartments that receive two corresponding pluggable modules therein, the EMI absorber extending between the two internal compartments along the lower side of the body.

9. The cage of claim 1, wherein the EMI absorber extends over an interior segment of the lower wall of the body.

10. The cage of claim 1, wherein the EMI absorber is secured to the body of the cage over the lower wall using at least one of an interference fit, an adhesive, a tab, or a clip.

11. The cage of claim 1, wherein the EMI absorber comprises at least one of a magnetic elastomer, a ferrite-based material, carbonal iron, or a ferrite material in a binder.

12. A receptacle assembly for mating with a pluggable module, the receptacle assembly comprising:
a receptacle connector; and
a cage comprising a body having an upper wall, a lower wall, and side walls that extend from the upper wall to the lower wall, the body having a lower side along which the lower wall extends, a front end, and an internal compartment, the receptacle connector being held within the internal compartment, the internal compartment being configured to receive the pluggable module therein through the front end, the cage being configured to be mounted to a printed circuit along the lower side, the lower side comprising a connector opening, wherein the cage comprises an electromagnetic interference (EMI) absorber that extends over at least a portion of the lower wall, the EMI absorber being configured to absorb EMI.

13. The receptacle assembly of claim 12, wherein the EMI absorber comprises a sheet of material that extends over a majority of a surface area of the lower wall.

14. The receptacle assembly of claim 12, wherein the EMI absorber comprises a cage opening that is at least partially aligned with the connector opening of the lower side such that the receptacle connector can communicate with the printed circuit through the cage and connector openings.

15. The receptacle assembly of claim 12, wherein the lower wall comprises a perimeter, the EMI absorber extending along the perimeter of the lower wall.

16. The receptacle assembly of claim 12, wherein the EMI absorber is secured to the body of the cage over the lower wall using at least one of an interference fit, an adhesive, a tab, or a clip.

17. The receptacle assembly of claim 12, wherein the EMI absorber comprises at least one of a magnetic elastomer, a ferrite-based material, carbonal iron, or a ferrite material in a polymer binder.

18. The receptacle assembly of claim 12, wherein the EMI absorber comprises an approximately planar sheet of material that extends over an interior segment of the lower wall of the body.

19. A cage for a receptacle assembly that includes a receptacle connector, the cage comprising:
a body comprising an upper wall, a lower wall, and side walls that extend from the upper wall to the lower wall, the body having a lower side along which the lower wall extends, a front end, and an internal compartment, the internal compartment being configured to hold the receptacle connector therein, the internal compartment being configured to receive a pluggable module therein through the front end, the cage being configured to be mounted to a printed circuit along the lower side, the lower side comprising a connector opening; and
an electromagnetic interference (EMI) absorber configured to absorb EMI, the EMI absorber extending along a perimeter of the lower wall.

20. The cage of claim 19, wherein the EMI absorber comprises a sheet of material that extends over a majority of a surface area of the lower wall.
